(19) United States
(12) Patent Application Publication
(10) Pub. No.: US 2021/0278442 A1
(43) Pub. Date: Sep. 9, 2021

(54) SENSOR WITH INSULATING ELEMENT FOR HIGH VOLTAGE SEPARABLE CONNECTORS

(71) Applicant: 3M INNOVATIVE PROPERTIES COMPANY, St. Paul, MN (US)

(72) Inventors: Christopher R. WILSON, Austin, TX (US); Jaylon D. LOYD, Austin, TX (US); Carl J. WENTZEL, Austin, TX (US)

(21) Appl. No.: 17/250,378

(22) PCT Filed: Jun. 27, 2019
(86) PCT No.: PCT/IB2019/055444

§ 371 Date: Jan. 13, 2021

Related U.S. Application Data
(60) Provisional application No. 62/699,220, filed on Jul. 17, 2018.

(51) Int. Cl. G01R 15/16; H01R 13/53; H01R 13/66

(52) U.S. Cl. CPC G01R 15/16; H01R 13/6683; H01R 13/53

(57) ABSTRACT

A sensor for a separable connector comprising an elongate insulating plug body extending along an axis. The sensor includes a high voltage connection at least partially encased by the insulating resin and comprising a receptacle configured to receive a high voltage conductor of the separable connector. The sensor also includes a high voltage capacitor comprising an insulating element at least partially encased by the insulating resin. An inner conductive layer is disposed on the inner surface of the insulating element and is electrically coupled to the high voltage connection. An outer conductive layer is disposed on the outer surface of the insulating element being capacitively coupled to the inner conductive layer. A low voltage connection is coupled to the outer conductive layer and one or more low voltage capacitors are electrically coupled to the low voltage connection to form a capacitive voltage divider.

### TECHNICAL FIELD

This disclosure relates to sensors for high voltage and, in particular, relates to sensors for high voltage separable connectors that have an elongate plug body and a high voltage capacitor including an insulating element that is stable over a broad temperature range.

### BACKGROUND

As electrical power distribution becomes more complex through the advent of renewable energy, distributed generation, and the adoption of electric vehicles, intelligent electrical distribution and associated electrical sensing is becoming more useful and even necessary. Useful sensing may include voltage, current, and the time relationship between voltage and current at various locations within a power distribution network.

Many existing relatively high voltage transformers and switchgears have a dedicated space for cable accessories, particularly in higher voltage applications (for example, 5 kV to 69 kV, or higher). Many of these transformers and switchgear are of a variety referred to in the power utility industry as dead-front. Dead-front means there are no exposed relatively high voltage surfaces in the connection between a power cable and the transformer or switchgear. Such cable accessory connections are sometimes referred to as elbows, T-bodies, or separable connectors.

Many cable accessories implement testpoints to provide a scaled fraction of the line voltage residing on the shielded and insulated conductor of the cable accessory. The historical use of these test points is for indication of the presence of line voltage at the transformer or switchgear. Often, these testpoints do not provide the voltage ratio accuracy required for modern grid automation power quality and control applications, particularly over a broad range of operating temperatures. Further, servicing some sensors requires an outage, which may be undesirable in many applications.

### SUMMARY

Various embodiments of the present disclosure relate to sensors for high voltage, which may also serve as an insulating plug. This disclosure includes sensors that have an elongate plug body and a high voltage capacitor including an insulating element. An inner conductive layer may be disposed on an inner surface of the insulating element and an outer conductive layer may be disposed on an outer surface of the insulating element. The inner and outer conductive layers may be capacitively coupled to form a capacitive voltage divider. In one or more embodiments, the inner and outer conductive layers overlap. The insulating element may be formed of a material that facilitates a stable capacitance over a broad temperature range to provide an accurate low voltage signal from the capacitive voltage divider.

In one aspect, the present disclosure relates to a sensor for a separable connector comprising an elongate plug body extending along an axis, the plug body comprising an insulating resin. The sensor includes a high voltage connection at least partially encased by the insulating resin and comprising a receptacle configured to receive a high voltage conductor of the separable connector. The sensor also includes a high voltage capacitor comprising an insulating element at least partially encased by the insulating resin, the insulating element comprising a wall portion extending around the axis between first and second end portions, the insulating element comprising an inner surface defining a cavity that at least partially receives the high voltage connection and comprising an outer surface surrounding the inner surface. An inner conductive layer is disposed on the inner surface of the insulating element and is electrically coupled to the high voltage connection. An outer conductive layer is disposed on the outer surface of the insulating element being capacitively coupled to the inner conductive layer. A low voltage connection is coupled to the outer conductive layer and one or more low voltage capacitors are electrically coupled to the low voltage connection to form a capacitive voltage divider.

It is to be understood that both the foregoing general description and the following detailed description present embodiments of the subject matter of the present disclosure, and are intended to provide an overview or framework for understanding the nature and character of the subject matter of the present disclosure as it is claimed.

### BRIEF DESCRIPTION OF THE DRAWINGS

FIG. 1 shows a diagram view of a system including a sensor, a separable connector, and an insulating cap.

FIG. 2 shows a cross-sectional view of a sensor for use with the system of FIG. 1 including a high voltage capacitor.

FIG. 3 shows a perspective view of the high voltage capacitor of FIG. 2 with a high voltage connection.

FIG. 4 shows a perspective view of the high voltage capacitor of FIG. 2 without the high voltage connection.

FIG. 5 shows a perspective view of another sensor for use with the system of FIG. 1 including a high voltage capacitor.

The disclosure may be more completely understood in consideration of the following detailed description of various embodiments of the disclosure and the accompanying drawings.

### DETAILED DESCRIPTION

The present disclosure relates to sensors for high voltage separable connectors having a plug body and a high voltage capacitor including an insulating element. Although reference is made herein to high voltage separable connectors, the sensor may be used with any voltage connector. Various other applications will become apparent to one of skill in the art having the benefit of the present disclosure.

It would be beneficial to provide a convenient and easy-to-use voltage sensor for a high voltage separable connector. The sensor may serve as an insulating plug that is free of exposed high voltage surfaces when inserted into the separable connector. The high voltage capacitor including the insulating element may be sized and shaped to withstand electrical field stress from a high voltage separable connector electrically coupled to an inner conductive layer disposed on the insulating element. A low voltage connection coupled to an outer conductive layer disposed on the insulating element may be electrically coupled to one or more low voltage capacitors to form a capacitive voltage divider that may be used to accurately measure a signal representing the high voltage present in the separable connector over a broad temperature range. Further, service of some sensor components may not require an outage.

The present disclosure provides a sensor for a separable connector, which may also be used as an insulating plug. The sensor includes a plug body. The plug body may be elongate and extend along an axis. The plug body may include an insulating resin. A high voltage connection may be used to electrically couple the sensor to the separable connector, particularly to couple to a high voltage conductor of the separable connector. The high voltage connection may be at least partially encased by the insulating resin. A high voltage capacitor may be electrically coupled to the high voltage connection. In particular, an inner conductive layer disposed on an inner surface of an insulating element may be electrically coupled to the high voltage connection. The inner surface may define a cavity that at least partially receives the high voltage connection. The insulating element may include a wall portion extending around the axis between first and second end portions. An outer conductive layer may be disposed on an outer surface of the insulating element, which may be capacitively coupled to the inner conductive layer. A low voltage connection may be coupled to the outer conductive layer. One or more low voltage capacitors may be electrically coupled to the low voltage connection to form a capacitive voltage divider. The low voltage connection may be used to electrically couple the sensor to other equipment, such as monitoring equipment or signal conditioning circuitry directly connected or in close proximity before being coupled to other equipment. The insulating element may be formed of a material that facilitates a stable capacitance over a broad temperature range to provide an accurate low voltage signal from the capacitive voltage divider.

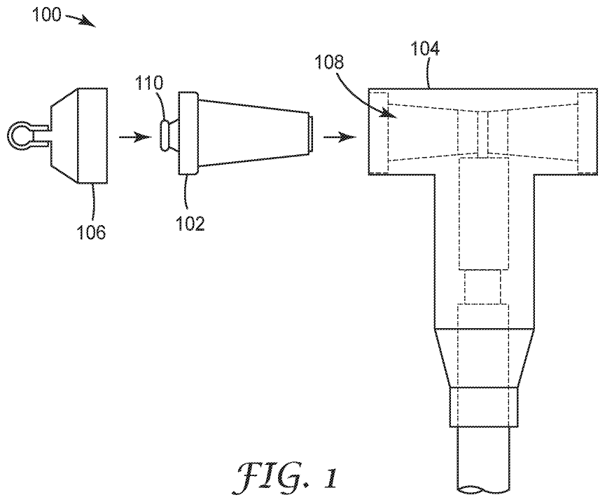

FIG. 1 shows a system 100 including a sensor 102, a separable connector 104, and an insulating cap 106. The system 100 and components thereof may be sized and shaped to meet, or otherwise be compatible with, an applicable standard, jurisdictional requirement, or end-user requirement for separable insulated connector systems. For example, the system 100 may be designed to meet the IEEE Standard 386 (2016) for an insulating plug for a separable connector. Specifically, the sensor 102 may be designed to be used as a 600A insulating plug. As another example, the system 100 may be designed to meet a similar International Electrotechnical Commission (IEC) standard, popular in Europe, which may employ a different size and shape for compatibility.

As illustrated, the sensor 102 may be in the shape of an insulating plug. The sensor 102 may be inserted into a receptacle 108 of the separable connector 104 and encase, or otherwise cover, a high voltage conductor, or high voltage conductive surface, disposed within the cavity. The separable connector 104 may include one, two, or more receptacles 108 (for example, in a T-Body).

The sensor 102 may be inserted in the same manner as a conventional insulating plug. In some embodiments, the sensor 102 may include a shoulder and a taper and the receptacle 108 has complimentary features. The high voltage conductor of the separable connector 104 may be in the shape of a threaded rod, and the sensor 102 may include a high voltage connection that has a complementary thread. The sensor 102 may be screwed onto the threaded high voltage conductor to secure the sensor 102 to the separable connector 104.

After being inserted and optionally secured, the sensor 102 may cover all, or at least some, high voltage surfaces in the receptacle 108 that would be otherwise exposed. An extending portion 110 of the sensor 102 may extend out of the receptacle 108 of the separable connector 104. The extending portion 110 may include a torque feature, such as a hex-shaped protrusion. The insulating cap 106 may be disposed over at least a portion of the sensor 102 to cover the extending portion 110. In some embodiments, the insulating cap 106 may be considered part of the sensor 102, for example, to carry out various functionality of the sensor. The insulating cap 106 may be frictionally secured to the separable connector 104. The insulating cap 106 may slide over at least a portion of the separable connector 104 and may be pulled off to expose at least a portion of the sensor 102. In some embodiments, extending portion 110 of the sensor 102 may have an outer surface that is formed of insulating material, and the insulating cap 106 may not be needed.

The sensor 102 may be a voltage sensor. The sensor 102 may provide a low voltage signal that corresponds to a high voltage signal present in the separable connector 104. The low voltage signal may be described as a voltage channel. The sensor 102 may include one or more capacitors. In some embodiments, capacitors include at least a low voltage capacitor and at least a high voltage capacitor. The capacitors may be arranged as a voltage divider to provide the low voltage signal. For example, the low voltage signal may correspond to the divided voltage signal.

The sensor 102 may provide an accuracy of the low voltage signal representing the high voltage signal that enables use in various smart grid applications for diagnosing degradation or other problems in the connected transformer, switchgear, or the larger connected grid, such as dips, sags, swells and other events. A higher accuracy sensor may facilitate the detection of smaller events or may facilitate more precise diagnosis of events. For example, for VOLT VAR control, a certain accuracy (for example, about 0.7%) may be required to detect changes in the system, such as when on-load tap changers in transformers are changed. The accuracy may be defined as being less than or equal to an error value. Non-limiting examples of the error value include about 1%, about 0.7%, about 0.5%, about 0.3%, about 0.2%, about 0.1%, or less.

The temperature range over which the sensor 102 is accurate may be described as an operating temperature range. In the operating temperature range, the accuracy may be less than or equal to the error value for all temperatures within the range. The operating temperature range may be designed to meet a standard, jurisdictional requirement, or end-user requirement. Non-limiting examples of the operating temperature range include a lower end equal to or greater than about −40° C., about −30° C., about −20° C., about −5° C., or higher. Non-limiting examples of the operating temperature range include a higher end equal to or less than about 105° C., about 85° C., about 65° C., about 40° C., or lower. Non-limiting examples of the operating temperature range include being between about −5° C. to about 40° C., about −20° C. to about 65° C., about −30° C. to about 85° C., about −40° C. to about 65° C., and about −40° C. to about 105° C.

The sensor 102 may have a voltage rating, or be rated, to operate in high voltage systems, such as system 100. The sensor 102 may operate as a voltage sensor, an insulating plug, or both. The voltage rating may be designed to meet a standard, jurisdictional requirement, or end-user requirement. Non-limiting examples of the voltage rating of the sensor 102 in a three-phase system include about 2.5 kV, about 3 kV, about 5 kV, about 15 kV, about 25 kV, about 28 kV, about 35 kV, or about 69 kV (classified as phase-to-phase rms). In some embodiments, the voltage rating is at least about 5 kV.

The frequency range over which the sensor 102 is accurate may be described as an operating frequency range. The frequency response may be flat or substantially flat, which may correspond to minimum variation, over the operating frequency range. Non-limiting examples of flatness may include plus or minus (+/−) about 3 dB, about 1 dB, about 0.5 dB, and about 0.1 dB. The frequency response may be designed to meet a standard, jurisdictional requirement, or end-user requirement. The operating frequency range may extend to about the 50th harmonic, or even up to the 63rd harmonic, of a base frequency of the high voltage signal present in the separable connector 104. Non-limiting examples of the operating frequency range may include one or more of the base frequency of about 60 Hz (or about 50 Hz), the 50th harmonic of about 3 kHz (or about 2.5 kHz), the 63rd harmonic of about 3.8 kHz (or about 3.2 kHz), and higher. The frequency response may also remain stable over all or substantially all the operating temperature range. Certain remote terminal units (RTUs) or intelligent electronic devices (IEDs) may take advantage of one or more of these higher order harmonics.

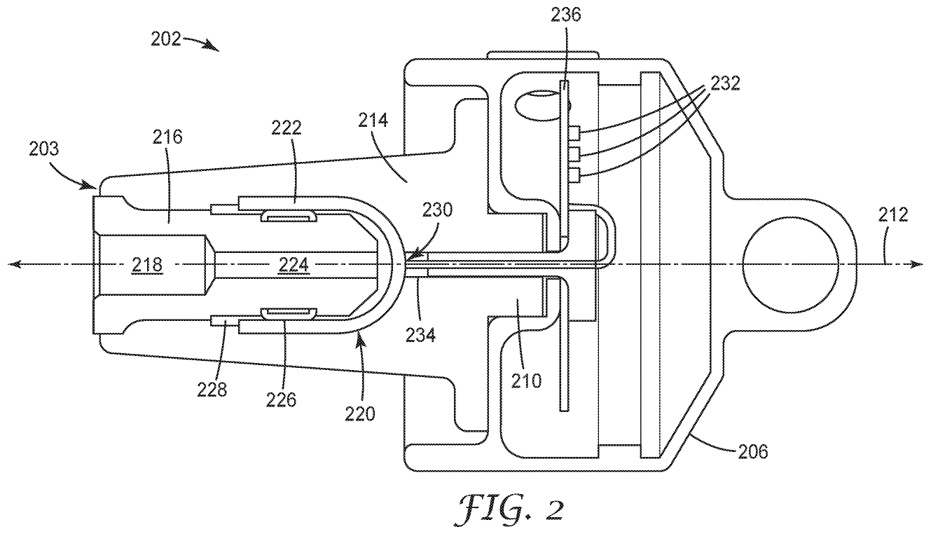

FIG. 2 shows a sensor 202 in a cross-sectional view along an axis 212. The axis 212 may be described as being parallel to a longitudinal direction and orthogonal to a lateral direction. As illustrated, the sensor 202 may include a plug body 203 coupled to an insulating cap 206. The plug body 203 may be elongate and extend along the axis 212. The sensor 202 may further include one or more of an extending portion 210 of the plug body 203, a high voltage connection 216, a receptacle 218 formed in the high voltage connection to receive the high voltage conductor of the separable conductor, a high voltage capacitor 220, a compressible contact 226 electrically coupled to the high voltage connection, a sealing element 228, a low voltage connection 230, one or more low voltage capacitors 232 electrically coupled to the low voltage connection to form a capacitive voltage divider, a separable coupling element 234, and a substrate 236. The capacitive voltage divider formed by the sensor 202 may provide a low voltage signal between the high voltage capacitor 220 and the one or more low voltage capacitors 232 that represents a fraction of the high voltage signal received by the high voltage connection 216 relative to an electrical ground.

One or more components of the sensor 202 may be separably coupled. For example, one or more components of the sensor 202 may be disposed in the insulating cap 206 and separably coupled to one or more remaining components disposed in the plug body 203 of the sensor. In some embodiments, one or more components of the sensor 202 may be integrally formed together, such as the plug body 203 and the insulating cap 206. The separable coupling may facilitate servicing some components of the sensor 202 without an outage, such as the low voltage capacitors 232 and any other conditioning or data storage components that may require more frequent servicing than other components (for example, compared to the high voltage capacitor 220).

The plug body 203 may include an insulating resin 214. The resin 214 may insulate components of the sensor 202, such as the high voltage connection 216, to isolate the high voltage conductor of the separable connector from the ambient environment and any sensitive components of the sensor. In some embodiments, the resin 214 may at least partially encase one or more of the high voltage connection 216, the high voltage capacitor 220, the low voltage connection 230, the one or more low voltage capacitors 232, and other components of the sensor 202.

The resin 214 may include any suitable electrically insulating, or dielectric, material or materials. The resin 214 may be formed by any suitable process, such as overmolding. In some embodiments, the high voltage connection 216 and the high voltage capacitor 220 may be placed in a mold and the resin 214 may be formed around these components. An outer shape of the resin 214 may at least partially define an outer shape of the plug body 203.

Before the resin 214 is molded around the high voltage connection 216 and the high voltage capacitor 220, the sealing element 228 may be disposed adjacent to both components to provide a seal therebetween. In some embodiments, the high voltage connection 216 may be at least partially disposed in a cavity 224 of the high voltage capacitor 220, and the sealing element 228 may prevent the resin 214 from entering the cavity 224. In particular, the cavity 224 may be at least partially defined by an insulating element 222 of the high voltage capacitor 220. As a result, the cavity 224 may be free of resin 214. The sealing element 228 may be formed of any suitable material. A non-limiting example of such material includes a silicone material.

The sealing element 228 may at least partially extend around the axis 212 and may at least partially extend around the high voltage connection 216. In some embodiments, the sealing element 228 may extend entirely around the axis 212 or the high voltage connection 216. A non-limiting example of the shape of the sealing element 228 includes a ring shape. The sealing element 228 may or may not be electrically conductive.

The compressible contact 226 may be electrically conductive. The compressible contact 226 may at least partially extend around the axis 212 and may at least partially extend around the high voltage connection 216. In some embodiments, the compressible contact 226 may extend entirely around the axis 212 or the high voltage connection 216. A non-limiting example of the shape of the compressible contact 226 includes a ring shape.

The compressible contact 226 may laterally compressible and disposed between the high voltage connection 216 and the insulating element 222. In some embodiments, the high voltage connection 216 may have a different coefficient of thermal expansion (CTE) than the insulating element 222. The compressible contact 226 may allow the high voltage connection 216 to expand within the cavity 224 of the high voltage capacitor 220 to facilitate electrical coupling of these components through a broad range of operating temperatures.

Any suitable type of compressible contact 226 may be used. In some embodiments, the compressible contact may include a compliant spring contact. For example, the compressible contact may include a spring lamella contact or a canted coil spring contact.

The high voltage connection 216 may be in direct contact with the high voltage conductor of the separable connector. The high voltage connection 216 may be formed of any suitable material. Non-limiting examples of suitable material include one or more of aluminum and steel. The CTE of the material may be matched to the high voltage conductor of the separable connector.

The low voltage connection 230 may be electrically coupled to the high voltage capacitor 220. The low voltage connection 230 may provide an interface for a low voltage signal representing the high voltage present in the separable connector to be measured by external instruments. The low voltage signal may be conditioned before leaving the sensor.

In some embodiments, the low voltage connection 230 may be at least partially integrally formed with the high voltage capacitor 220. For example, the low voltage connection 230 may be formed as a conductor or part of a conductor of the high voltage capacitor 220. In some embodiments, the low voltage connection 230 may include the separable coupling element 234. The separable coupling element 234 may allow the high voltage capacitor 220 to be separably electrically coupled to the one or more low voltage capacitors 232. For example, the one or more low voltage capacitors 232 may be disposed on the substrate 236 and electrically coupled to a first portion of the separable coupling element 234. The low voltage capacitors 232, the substrate 236, and the first portion of the separable coupling element 234 may be coupled to and at least partially disposed in the insulating cap 206, which may be removable from the plug body 203. A second portion of the separable coupling element 234 may be coupled to the high voltage capacitor 220. When the first and second portions of the separable coupling element 234 are electrically coupled, the low voltage capacitors 232 may be operatively coupled to the high voltage capacitor 220 to form the capacitive voltage divider. A non-limiting example of a separable coupling element 234 includes a pogo pin spring contact. A non-limiting example of a substrate 236 includes a printed circuit board.

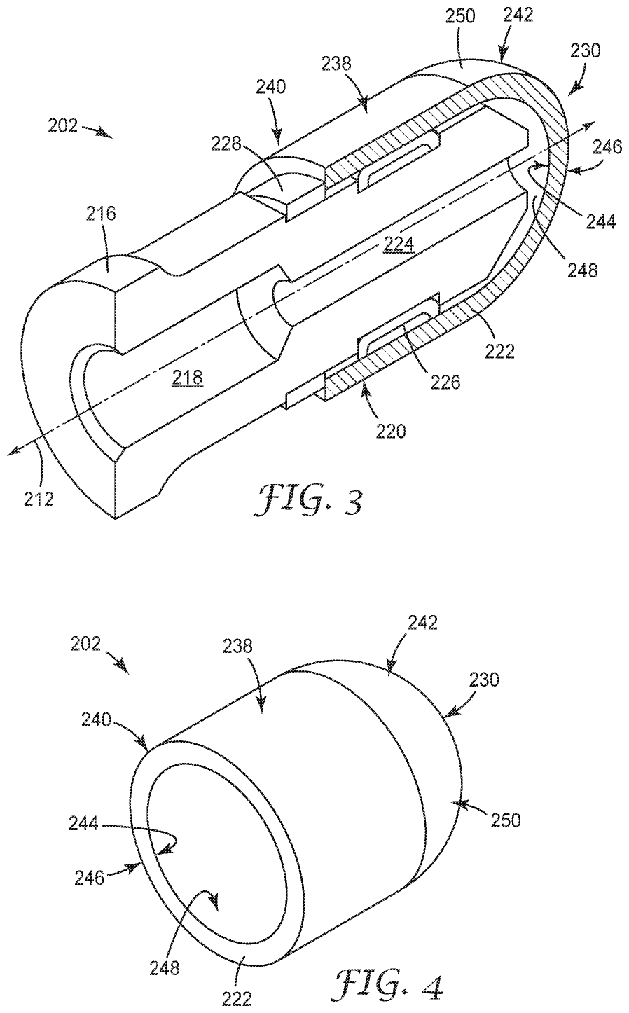

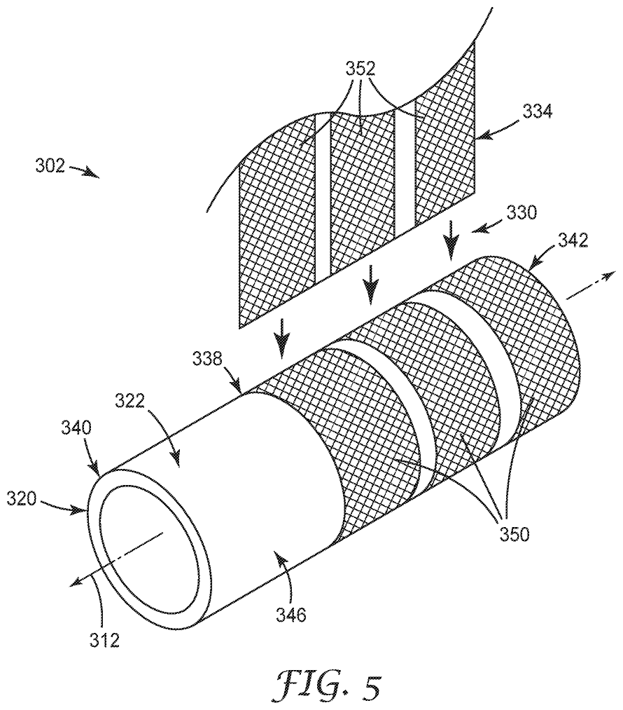

FIG. 3 and FIG. 4 show various components of a sensor 202, particularly the high voltage capacitor 220, which may be used with systems, such as system 100 (FIG. 1). The high voltage capacitor 220 may include the insulating element 222 having a wall portion 238 extending around the axis 212 between a first end portion 240 and a second end portion 242, an inner conductive layer 248 disposed on an inner surface 244 of the insulating element, and an outer conductive layer 250 disposed on an outer surface 246 of the insulating element. The outer surface 246 of the insulating element 222 may surround the inner surface 244. In some embodiments, the low voltage connector 230 may be at least partially integrally formed with or may be described as part of the outer conductive layer 250.

The inner surface 244 of the insulating element 222 may define the cavity 224 that may at least partially receive the high voltage connection 216 having receptacle 218. The sealing element 228 may be disposed adjacent to the first end portion 240 of the insulating element 222 and the high voltage connection 216 to provide a seal during manufacturing of the sensor 202. In some embodiments, the sealing element 228 may be disposed proximate to, adjacent to, or at least partially disposed in the cavity 224. The inner conductive layer 248 may be electrically coupled to the high voltage connection 216 via the compressible contact 226. The compressible contact 226 may be coupled to both the high voltage connection 216 and the inner conductive layer 248. The outer conductive layer 250 may be coupled to the low voltage connection 230. The outer conductive layer 250 may be capacitively coupled to the inner conductive layer 248 through the insulating element 222, which may serve as the dielectric of a capacitor.

At least part of the inner surface 244 may be covered by the inner conductive layer 248. The inner conductive layer 248 may be at least partially disposed on the inner surface 244 of one or more of the wall portion 238, the first end portion 240, and the second end portion 242. In some embodiments, the inner conductive layer 248 may be disposed on the entire inner surface 244 of the insulating element 222.

At least part of the outer surface 246 may be covered by the outer conductive layer 250. The outer conductive layer 250 may be at least partially disposed on the outer surface 246 of one or more of the wall portion 238, the first end portion 240, and the second end portion 242. For example, as illustrated, the outer conductive layer 250 may be disposed only on the second end portion 242.

The outer conductive layer 250 may at least partially overlap the inner conductive layer 248. In other embodiments, the outer conductive layer 250 may not overlap the inner conductive layer 248. As used herein, “overlap” may refer both the inner conductive layer 248 and the outer conductive layer 250 being disposed on a same portion of the insulating element 222. In another manner of characterization, a normal to a portion of the outer conductive layer 250 may extend through a portion of the inner conductive layer 248 disposed directly on the opposite side of the insulating element 222 from the portion of the outer conductive layer. In some embodiments, the entire outer conductive layer 250 may overlap at least a portion of the inner conductive layer 248. For example, as illustrated, the outer conductive layer 250 may be disposed on the entire second end portion 242 and overlap the inner conductive layer 248 in the second end portion 242.

The amount of overlap, or in other words, the surfaces of each conductive layer 248, 250 that overlap one another, may affect the capacitance of the high voltage capacitor 220. For example, a greater area of overlap may result in a greater capacitance value of the high voltage capacitor 220.

The inner and outer conductive layers 248, 250 may be disposed on the insulating element 222 in any suitable manner. Non-limiting examples of techniques to dispose the conductive layers 248, 250 on the insulating element 222 include conductive painting, vapor deposition, and chemical deposition. In some embodiments, the inner and outer conductive layers 248, 250 may be described as plated conductors.

The insulating element 222 may be disposed between the high voltage connection 216 and the low voltage connection 230, which may facilitate capacitive coupling between the connections 216, 230. The second end portion 242 may be a closed end portion. Non-limiting examples of the shape of the second end portion 242 include a dome shape and a cylindrical-end shape. As illustrated, the second end portion 242 may be a dome shape. The dome shape may also be described as a hemi-spherical shape. In some embodiments, the high voltage capacitor 220 may be a hemispherical capacitor having a second end portion 242 including a hemispherical shape.

The first end portion 240 may be an open-end portion. The first end portion 240 may define an opening for the cavity 224 to receive the high voltage connection 216. The first end portion 240 may have a cross-sectional shape orthogonal to the axis 212 that may be the same or similar to the cross-sectional shape of the wall portion 238. The wall portion 238 may include a cylindrical shape. Non-limiting examples of the cross-sectional shape of the wall portion 238 include an annular shape, an ovate shape, or a circular shape.

The insulating element 222 may provide a dielectric around the high voltage connection 216 inserted into the cavity 224. The insulating element 222 may be any suitable size and shape to provide electrical insulation between the inner and outer conductive layers 248, 250. The insulating element 222 may have a thickness that is uniform or non-uniform along one or more of the wall portion 238, the first end portion 240, and the second end portion 242.

The insulating element 222 may be formed of any suitable material to provide electrical insulation. Non-limiting examples of material for the insulating element 222 include one or more of a ceramic material, a glass material, and a crystalline material. The material of the insulating element 222 may provide mechanical or electrical properties that are stable over a broad temperature range. In particular, the insulating element 222 may provide a stable nominal capacitance value between the inner and outer conductive layers 248, 250 to facilitate an accurate low voltage signal from the capacitive voltage divider. The insulating element 222 may be capable of electrically insulating the inner conductive layer 248 from the outer conductive layer 250 over a broad operating temperature range, for example, including about −40° C. to about 105° C. The nominal capacitance value of the high voltage capacitor 220 may remain substantially the same over the operating temperature range. For example, a stable nominal capacitance value may change less than or equal to about 25%, about 20%, about 15%, about 10%, about 5%, about 2%, about 1%, about 0.5%, about 0.1%, or less.

The high voltage capacitor 220 may be rotationally symmetric about the axis 212. In particular, the insulating element 222 may be rotationally symmetric about the axis 212. However, in other embodiments, the high voltage capacitor 220 and its various components may not be rotationally symmetric about the axis 212.

FIG. 5 shows various components of a sensor 302, particularly the high voltage capacitor 320, which may be used with systems, such as system 100 (FIG. 1). Many of the parts and components depicted in FIG. 5 are the same or similar to those depicted in, and described with regard to, FIG. 2 through FIG. 4. Reference is made to the discussion above regarding FIG. 2 through FIG. 4 for elements depicted in, but not specifically discussed with regard to, FIG. 5. The sensor 302 may have a length along the axis 312 that is greater than or equal to the length of the sensor 202 (FIG. 2) along the axis 212 (FIG. 2).

In some embodiments, as shown in FIG. 5, the sensor 302 may include a cylindrical shape. In particular, the second end portion 342 of the insulating element 322 may include a cylindrical-end shape. The second end portion 342 may be a closed end portion. The first end portion 340 may be an open-end portion.

The outer conductive layer 350 may be disposed at least partially on the outer surface 346 of the wall portion 338 extending between the first and second end portions 340, 342. In some embodiments, the outer conductive layer 350 may be disposed only on the wall portion 338. The outer conductive layer 350 may include a plurality of discrete conductors. The outer conductive layer 350 may include at least one ring-shaped conductor. Any or all of the discrete conductors may be ring-shaped conductors. In some embodiments, the plurality of discrete conductors of the outer conductive layer 350 may include three discrete conductors spaced along the axis 312.

A low voltage connection 330 may be electrically coupled to the outer conductive layer 350. In some embodiments, the low voltage connection 330 may be integrally formed with the outer conductive layer 350. In some embodiments, the low voltage connection 330 may include a flex circuit 334 electrically coupled to the plurality of discrete conductors.

The flex circuit 334 may include one or more conductive paths 352. The flex circuit 334 may include one or more of a flexible ribbon cable, a wire conductor, a trace, and a flexible printed circuit board. In some embodiments, the flex circuit 334 may include at least two conductive paths 352 electrically isolated from one another. At least one of the conductive paths 352 of the flex circuit 334 may be electrically coupled to a ground. At least one of the conductive paths of the flex circuit 334 may be electrically coupled to the low voltage connection 330, for example, between the high voltage capacitor 320 and one or more low voltage capacitors (not shown) to provide a low voltage signal. In some embodiments, the conductive path 352 electrically coupled to the low voltage connection 330 may be disposed between two or more conductive paths electrically coupled to the ground, which may reduce fringe effects.

Thus, various embodiments of the SENSOR WITH INSULATING ELEMENT FOR HIGH VOLTAGE SEPARABLE CONNECTORS are disclosed. Although reference is made herein to the accompanying set of drawings that form part of this disclosure, one of at least ordinary skill in the art will appreciate that various adaptations and modifications of the embodiments described herein are within, or do not depart from, the scope of this disclosure. For example, aspects of the embodiments described herein may be combined in a variety of ways with each other. Therefore, it is to be understood that, within the scope of the appended claims, the claimed invention may be practiced other than as explicitly described herein.

All scientific and technical terms used herein have meanings commonly used in the art unless otherwise specified. The definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

The recitation of numerical ranges by endpoints includes all numbers subsumed within that range (for example 1 to 5 includes 1, 1.5, 2, 2.75, 3, 3.80, 4, and 5) and any range within that range. Herein, the terms “up to” or “no greater than” a number (for example, up to 50) includes the number (for example, 50), and the term “no less than” a number (for example, no less than 5) includes the number (for example, 5).

The terms “coupled” or “connected” refer to elements being attached to each other either directly (in direct contact with each other) or indirectly (having one or more elements between and attaching the two elements).

Terms related to orientation, such as “longitudinal,” “lateral,” and “end,” are used to describe relative positions of components and are not meant to limit the orientation of the embodiments contemplated. For example, an embodiment described as having an “end” also encompasses embodiments thereof rotated in various directions unless the content clearly dictates otherwise.

Reference to “one embodiment,” “an embodiment,” “certain embodiments,” or “some embodiments,” etc., means that a particular feature, configuration, composition, or characteristic described in connection with the embodiment is included in at least one embodiment of the disclosure. Thus, the appearances of such phrases in various places throughout are not necessarily referring to the same embodiment of the disclosure. Furthermore, the particular features, configurations, compositions, or characteristics may be combined in any suitable manner in one or more embodiments.

As used in this specification and the appended claims, the singular forms “a,” “an,” and “the” encompass embodiments having plural referents, unless the content clearly dictates otherwise. As used in this specification and the appended claims, the term “or” is generally employed in its sense including “and/or” unless the content clearly dictates otherwise.

As used herein, “have,” “having,” “include,” “including,” “comprise,” “comprising” or the like are used in their open-ended sense, and generally mean “including, but not limited to.” It will be understood that “consisting essentially of” “consisting of” and the like are subsumed in “comprising,” and the like.

The phrases “at least one of,” “comprises at least one of,” and “one or more of” followed by a list refers to any one of the items in the list and any combination of two or more items in the list.

1. A sensor for a separable connector comprising:
an elongate plug body extending along an axis, the plug body comprising an insulating resin;
a high voltage connection at least partially encased by the insulating resin and comprising a receptacle configured to receive a high voltage conductor of the separable connector;
a high voltage capacitor comprising:
an insulating element at least partially encased by the insulating resin, the insulating element comprising a wall portion extending around the axis between first and second end portions, the insulating element comprising an inner surface defining a cavity that at least partially receives the high voltage connection and comprising an outer surface surrounding the inner surface;
an inner conductive layer disposed on the inner surface of the insulating element and electrically coupled to the high voltage connection; and
an outer conductive layer disposed on the outer surface of the insulating element being capacitively coupled to the inner conductive layer;
a low voltage connection coupled to the outer conductive layer; and
one or more low voltage capacitors electrically coupled to the low voltage connection to form a capacitive voltage divider,
wherein the second portion is a closed end portion, and wherein the second end portion includes a dome shape.

2. The sensor of claim 1, wherein the outer conductive layer at least partially overlaps the inner conductive layer such that both the outer conductive layer and the inner conductive layer are disposed on a same portion of the insulating element.

3-4. (canceled)

5. The sensor of claim 1, wherein the second end portion includes a cylindrical-end shape, which may be open or close ended.

6. The sensor of claim 1, wherein the wall portion includes a cylindrical shape.

7. The sensor of claim 1, wherein the insulating element electrically insulates the inner conductive layer from the outer conductive layer over a broad operating temperature range including about −40° C. to about 105° C. and provides a stable nominal capacitance value over that temperature range.

8. The sensor of claim 1, wherein the insulating element comprises one or more of a ceramic material, a glass material, and a crystalline material.

9. The sensor of claim 1, wherein the insulating element comprises at least one of Aluminum Oxide (Al2O3), Fused Silica (SiO2), Mullite (3Al2O3-SiO2), Barium Titanate (BaTiO3), and Calcium Zirconate (CaZrO3).

10. The sensor of claim 1, wherein the outer conductive layer is disposed at least partially on the wall portion.

11. The sensor of claim 10, wherein the outer conductive layer comprises at least one ring-shaped conductor.

12. The sensor of claim 10, wherein the outer conductive layer comprises a plurality of discrete conductors.

13. The sensor of claim 12, wherein the plurality of discrete conductors comprises three discrete conductors spaced along the axis.

14. The sensor of claim 12, further comprising a flex circuit electrically coupled to the plurality of discrete conductors.

15. The sensor of claim 14, wherein the flex circuit comprises at least two conductive paths electrically isolated from one another.

16. (canceled)

17. The sensor of claim 1, wherein the inner conductive layer is disposed on the entire inner surface of the insulating element.

18. The sensor of claim 1, wherein the outer conductive layer is disposed only on the second end portion of the insulating element.

19-20. (canceled)

21. The sensor of claim 1, further comprising a compressible contact electrically coupling the high voltage connection to the inner conductive layer.

22-25. (canceled)

26. The sensor of claim 1, wherein the cavity is free of insulating resin.

27. The sensor of claim 1, further comprising a sealing element adjacent to the first end of the insulating element and the high voltage connection.

28-29. (canceled)

30. The sensor of claim 1, wherein the low voltage connection comprises a separable connector.

31. (canceled)

32. The sensor of claim 1, further comprising a substrate, the one or more low voltage capacitors being disposed on the substrate.
